(19) United States
(12) Patent Application Publication
(10) Pub. No.: US 2009/0236131 A1
(43) Pub. Date: Sep. 24, 2009

(54) Multilayered printed circuit board and method of manufacturing the same

(75) Inventors: Jee Soo Mok, Gyunggi-do (KR); Je Gwang Yoo, Gyunggi-do (KR); Chang Sup Ryu, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/222,055

(22) Filed: Jul. 31, 2008

(30) Foreign Application Priority Data
Mar. 18, 2008 (KR) 10-2008-0025034

(51) Int. Cl. H05K 1/09; H05K 3/02

(52) U.S. Cl. 174/257; 29/847

(57) ABSTRACT

Disclosed herein is a multilayered circuit board, including: a multilayered printed circuit board manufactured using the method includes an insulating resin layer having via holes, on one side of which a first circuit layer including circuit patterns is formed, and on the other side of which a second circuit layer, including connecting pads, is formed, the pads protruding over the via holes; a build-up layer formed on the first circuit layer, the build-up layer including a plurality of insulating layers and a plurality of circuit layers; and a solder resist layer formed on an outermost layer of the build-up layer.

### CROSS REFERENCE TO RELATED APPLICATION

This application claims the benefit of Korean Patent Application No. 10-2008-0025034, filed Mar. 18, 2008, entitled “Multilayered printed circuit board and fabricating method of the, same”, which is hereby incorporated by reference in its entirety into this application.

### BACKGROUND OF THE INVENTION

1. Field of the Invention

The present invention relates to a multilayered printed circuit board and a method of manufacturing the same, and, more particularly, to a multilayered printed circuit board which is thinner and has improved bending strength, and a method of manufacturing the same.

2. Description of the Related Art

Generally, printed circuit boards (PCBs) are manufactured by patterning one or both sides of a substrate, composed of various thermosetting resins, using copper foil, and disposing and fixing ICs or electronic parts on the substrate, thus forming electric circuits therebetween.

Recently, with the advancement of the electronics industry, electronic parts are increasingly required to be highly functionalized, and to be light, thin, short and small. Printed circuit boards loaded with such electronic parts are also required to be highly densified and thin.

In particular, since conventional build-up circuit boards are used as products in a state in which a build-up layer is formed on a core substrate, there is a problem in that the thickness of the build-up circuit board is increased. That is, when the thickness of the build-up circuit board is increased, there is also a problem in that the length of the circuit is increased, so that the signal processing time is increased, thereby preventing the circuit from being highly densified.

In order to overcome the above problems, a coreless substrate having no core is proposed. FIG. 1 shows a conventional process of manufacturing a coreless substrate. Hereinafter, the conventional process of manufacturing a coreless substrate will be described with reference to FIG. 1.

First, as shown in FIG. 1A, a metal carrier 10, used to support a coreless substrate during the process, is prepared.

Subsequently, as shown in FIG. 1B, a metal barrier 11 is formed on one surface of the metal carrier 10, and a circuit pattern 12 is formed on the metal barrier 11.

Subsequently, as shown in FIG. 1C, a build-up layer 13, including a plurality of insulation layers and a plurality of circuit layers, is formed on the circuit pattern 12. Here, the build-up layer is formed using a general build-up method.

Subsequently, as shown in FIG. 1D, the metal carrier 10 and the metal barrier are removed.

Finally, as shown in FIG. 1E, solder resist layers 14 are formed on the uppermost and lowermost layers of the build-up layer 13, respectively, thereby manufacturing a coreless substrate 15.

As such, the conventional coreless substrate 15 is manufactured by forming a build-up layer 13 through a metal carrier 10, functioning as a support, and then removing the metal carrier therefrom.

However, the conventional coreless substrate 15 is problematic in that it bends when it is put to practical use because the metal carrier 10 functions as a support during the process but is removed after the process.

Further, the conventional coreless substrate 15 is problematic in that an additional process for removing the metal carrier 10 is required, and solder resist layers 14 must be additionally formed in order to protect the circuit pattern exposed after the removal of the metal carrier 10.

### SUMMARY OF THE INVENTION

Accordingly, the present invention has been made keeping in mind the above problems occurring in the prior art, and the present invention provides a multilayered printed circuit board which is prevented from being bent after the manufacture thereof as well as during the manufacture thereof, and a method of manufacturing the same.

Further, the present invention provides a method of manufacturing a multilayered printed circuit board, in which an additional PSR process is not required because a support prevents the circuit board from being bent and functions as a solder resist layer, and a multilayered printed circuit board manufactured using the method.

A multilayered printed circuit board according to an aspect of the present invention includes: an insulating resin layer having via holes, on one side of which a first circuit layer including circuit patterns is formed, and on the other side of which a second circuit layer, including connecting pads for attaching solder balls thereto, is formed, the connecting pads protruding over the via holes; a build-up layer formed on the first circuit layer, the build-up layer including a plurality of insulating layers and a plurality of circuit layers; and a solder resist layer formed on an outermost layer of the build-up layer.

Here, the first circuit layer and the second circuit layer are formed of silver (Ag) paste.

Further, the multilayered printed circuit board further includes solder balls attached to the connecting pads of the second circuit layer.

A multilayered printed circuit board according to another aspect of the present invention includes: an insulating resin layer having via holes, on one side of which a first circuit layer including circuit patterns is formed, and on the other side of which connection parts for attaching solder balls thereto are formed, the connection parts corresponding to surfaces of the via holes; a build-up layer formed on the first circuit layer, the build-up layer including a plurality of insulating layers and a plurality of circuit layers; and a solder resist layer formed on an outermost layer of the build-up layer.

Here, the circuit patterns and the via holes are formed of silver (Ag) paste or copper plating.

Further, the multilayered printed circuit board further includes solder balls directly connected to the via holes in the other side of the insulating resin layer.

A method of manufacturing a multilayered circuit board according to an aspect of the present invention includes: providing a double-sided copper clad laminate including via holes formed therethrough and openings for forming circuit patterns, formed by patterning copper foil formed on one side thereof; filling the via holes and the openings with conductive paste; removing the copper foil from the double-sided copper clad laminate to form a first circuit layer including circuit patterns on one side thereof and to form a second circuit layer including connecting pads for attaching solder balls thereto on the other side thereof; forming a build-up layer on the first circuit layer, the build-up layer including a plurality of insulating layers and a plurality of circuit layers; and forming a solder resist layer on an outermost layer of the build-up layer.

In this case, the via holes are formed through laser drilling or mechanical drilling.

Further, the method of manufacturing a multilayered printed circuit board further includes, after the forming the solder resist layer, forming an opening in the solder resist layer through LDA (Laser Direct Ablation).

Further, in the removing the copper foil from the double-sided copper clad laminate, the copper foil is removed by etching it using an etchant selected from among an iron chloride etchant, a copper chloride etchant, an alkaline etchant, and a hydrogen peroxide/sulfuric acid etchant.

Furthermore, the conductive paste is not removed using the etchant.

A method of manufacturing a multilayered circuit board according to another aspect of the present invention includes: providing a double-sided copper clad laminate having blind via holes formed therethrough and openings for forming circuit patterns, formed by patterning copper foil formed on one side thereof, filling the blind via holes and the openings with conductive paste; removing the copper foil from the double-sided copper clad laminate to form a first circuit layer including circuit patterns on one side thereof and to form connection parts for attaching solder balls thereto on the other side thereof; forming a build-up layer on the first circuit layer, the build-up layer including a plurality of insulating layers and a plurality of circuit layers; and forming a solder resist layer on an outermost layer of the build-up layer.

In this case, the blind via holes are formed through laser drilling.

Further, the method of manufacturing a multilayered printed circuit board further includes: after the forming the solder resist layer, forming an opening in the solder resist layer through LDA (Laser Direct Ablation).

Further, in the removing the copper foil from the double-sided copper clad laminate, the copper foil is removed by etching it using an etchant selected from among an iron chloride etchant, a copper chloride etchant, an alkaline etchant, and a hydrogen peroxide/sulfuric acid etchant.

Furthermore, the conductive paste is not removed using the etchant.

A method of manufacturing a multilayered circuit board according to a further aspect of the present invention includes: providing a one-sided copper clad laminate including blind via holes formed therethrough and an insulating resin layer coated with copper foil on one side thereof; forming a circuit layer on the other side of the insulating resin layer through copper plating; forming a build-up layer on the circuit layer, the build-up layer including a plurality of insulating layers and a plurality of circuit layers; removing the copper foil from the one-sided copper clad laminate to form connection parts for attaching solder balls thereto on one side thereof; and forming a solder resist layer on an outermost layer of the build-up layer.

In this case, the blind via holes are formed through laser drilling.

Further, the method of manufacturing a multilayered printed circuit board further includes: after the forming the solder resist layer, forming an opening in the solder resist layer through LDA (Laser Direct Ablation).

### BRIEF DESCRIPTION OF THE DRAWINGS

The above and other objects, features and advantages of the present invention will be more clearly understood from the following detailed description taken in conjunction with the accompanying drawings, in which:

FIG. 1 is sectional views showing a conventional process of manufacturing a coreless substrate;

FIG. 2 is a sectional view showing a multilayered printed circuit board according to a first embodiment of the present invention;

FIG. 3 is a sectional view showing a multilayered printed circuit board according to a second embodiment of the present invention;

FIG. 4 is a sectional view showing a multilayered printed circuit board according to a third embodiment of the present invention;

FIG. 5 is sectional views showing a process of manufacturing the multilayered printed circuit board of FIG. 2;

FIG. 6 is sectional views showing a process of manufacturing the multilayered printed circuit board of FIG. 3; and

FIG. 7 is sectional views showing a process of manufacturing the multilayered printed circuit board of FIG. 4.

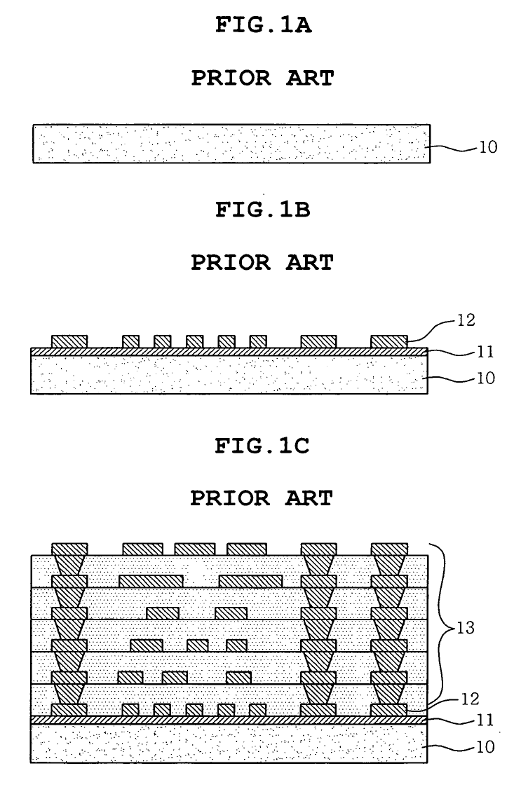

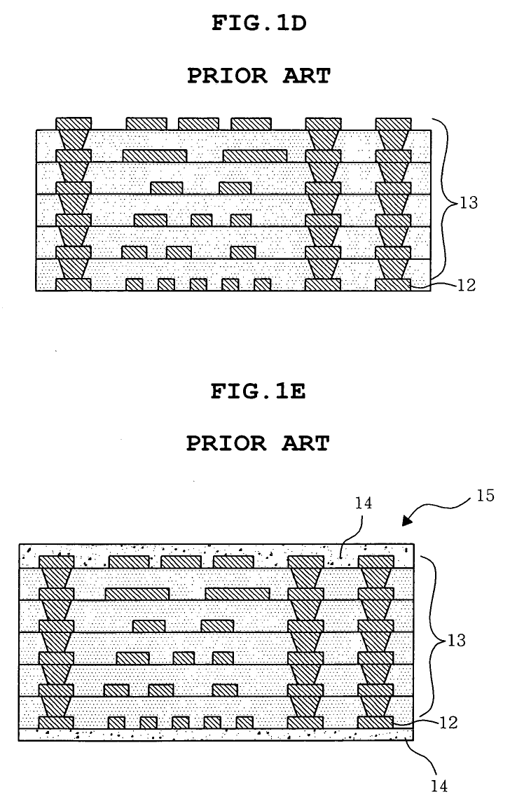

### DESCRIPTION OF THE PREFERRED EMBODIMENTS

Hereinafter, preferred embodiments of the present invention will be described in detail with reference to the attached drawings.

Reference now should be made to the drawings, in which the same reference numerals are used throughout the different drawings to designate the same or similar components.

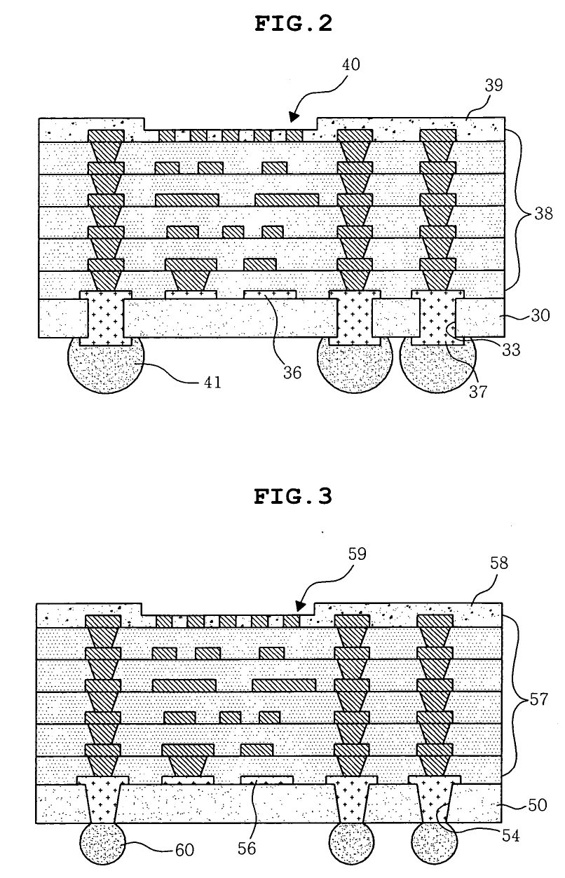

FIG. 2 is a sectional view showing a multilayered printed circuit board according to a first embodiment of the present invention.

The multilayered printed circuit board according to the first embodiment of the present invention includes an insulating resin layer 30, a build-up layer 38, and a solder resist layer 39.

The insulating resin layer 30 has via holes 33. A first circuit layer including circuit patterns 36 is formed on one side of the insulating resin layer 30, and a second circuit layer including protruding connecting pads 37 for attaching solder balls thereto is formed on the other side thereof.

Here, the first circuit layer and the second circuit layer are formed of conductive paste, for example, silver (Ag) paste.

Further, the solder balls 41 for connecting a main board or electronic products therewith are attached to the connecting pads 37.

The build-up layer 38 includes a plurality of insulating layers and a plurality of circuit layers, and is formed on the first circuit layer.

The solder resist layer 39 is formed on the outermost layer of the build-up layer 38 to protect circuit patterns and electrically insulate them. Further, the solder resist layer 39 is provided with an opening 40 to expose connecting terminals, formed on the outermost layer of the build-up layer 38, connected with other electronic products.

FIG. 3 is a sectional view showing a multilayered printed circuit board according to a second embodiment of the present invention.

The multilayered printed circuit board according to the second embodiment of the present invention includes an insulating resin layer 50, a build-up layer 57, and a solder resist layer 58. Here, the multilayered printed circuit board according to the second embodiment of the present invention is characterized in that the insulating resin layer 50 is not provided with protruding connecting pads.

The insulating resin layer 50 has via holes 54. A first circuit layer including circuit patterns 56 is formed on one side of the insulating resin layer 50.

Here, the first circuit layer is formed of conductive paste, for example, silver (Ag) paste.

Meanwhile, since protruding connecting pads are not formed beneath the insulating resin layer 50, solder balls 60 for connecting a main board or electronic products therewith are directly connected to conductive paste, that is, connection parts, charged in the via holes 54. Therefore, the solder balls 60 do not interfere with each other even when the pitch therebetween is short. That is, since the solder balls 60 (see FIG. 3) used in the second embodiment of the present invention have smaller diameters than the solder balls 41 (see FIG. 2) attached to the protruding connecting pads 37 (see FIG. 2) in the multilayered printed circuit board according to the first embodiment of the present invention, the solder balls 60 are advantageous when the pitch therebetween is short.

The build-up layer 57 includes a plurality of insulating layers and a plurality of circuit layers, and is formed on the first circuit layer.

The solder resist layer 58 is formed on the outermost layer of the build-up layer 57 to protect circuit patterns and electrically insulate them. Further, the solder resist layer 58 is provided with an opening 59 to expose connecting terminals, formed on the outermost layer of the build-up layer 57, connected with other electronic products.

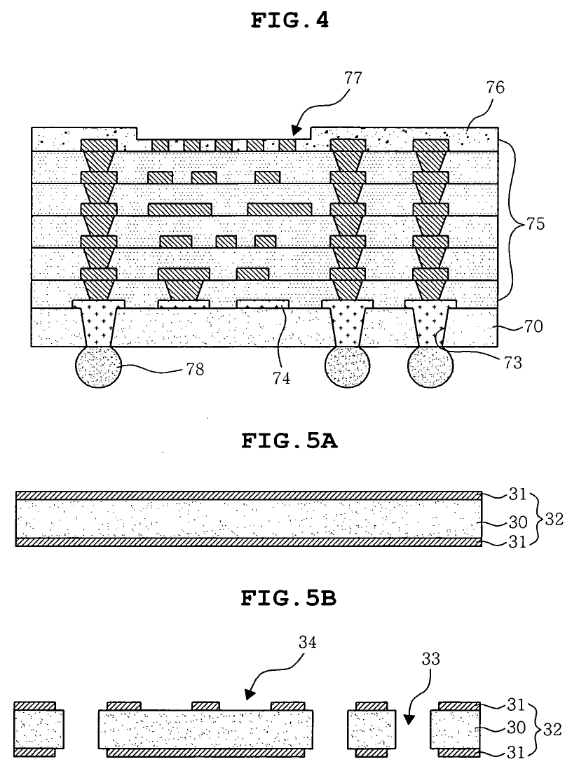

FIG. 4 is a sectional view showing a multilayered printed circuit board according to a third embodiment of the present invention.

The multilayered printed circuit board according to the third embodiment of the present invention includes an insulating resin layer 70, a build-up layer 75, and a solder resist layer 76. Here, the multilayered printed circuit board according to the third embodiment of the present invention is characterized in that the insulating resin layer 70 is not provided with protruding connecting pads, and circuit layers are formed through copper plating.

The insulating resin layer 70 has via holes 73. A first circuit layer including circuit patterns 74 is formed on one side of the insulating resin layer 70.

Here, the first circuit layer is formed through copper plating. Since the multilayered printed circuit board according to the third embodiment of the present invention includes the circuit layers formed through copper plating, it has higher signal conductivity than the multilayered printed circuit boards according to the first and second embodiment of the present invention, in which the circuit layers are formed of conductive paste.

Further, solder balls 78 for connecting a main board or electronic products therewith are directly connected to copper plating, that is, connection parts, formed in the via holes 73.

The build-up layer 75 includes a plurality of insulating layers and a plurality of circuit layers, and is formed on the first circuit layer.

The solder resist layer 76 is formed on the outermost layer of the build-up layer 75 to protect circuit patterns and electrically insulate them. Further, the solder resist layer 76 is provided with an opening 77 to expose connecting terminals, formed on the outermost layer of the build-up layer 75, connected with other electronic products.

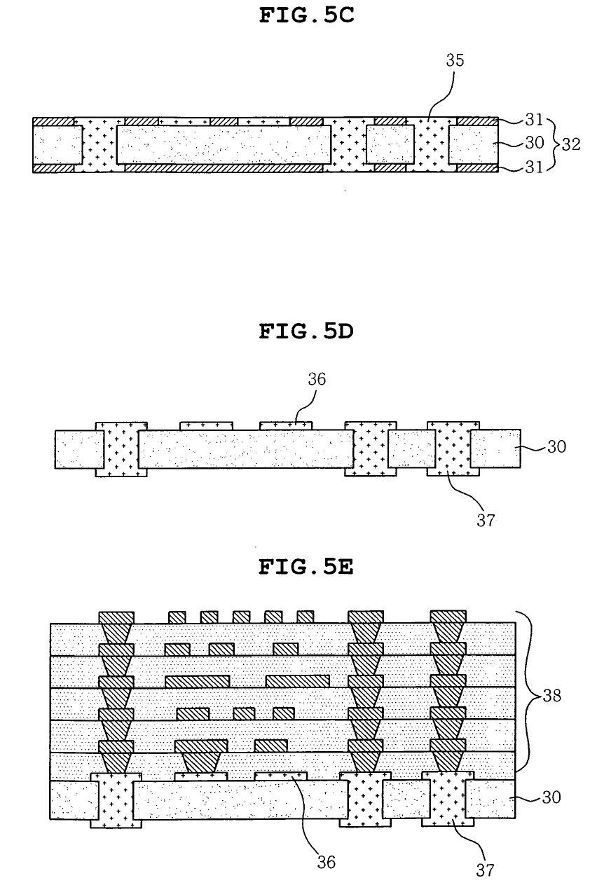

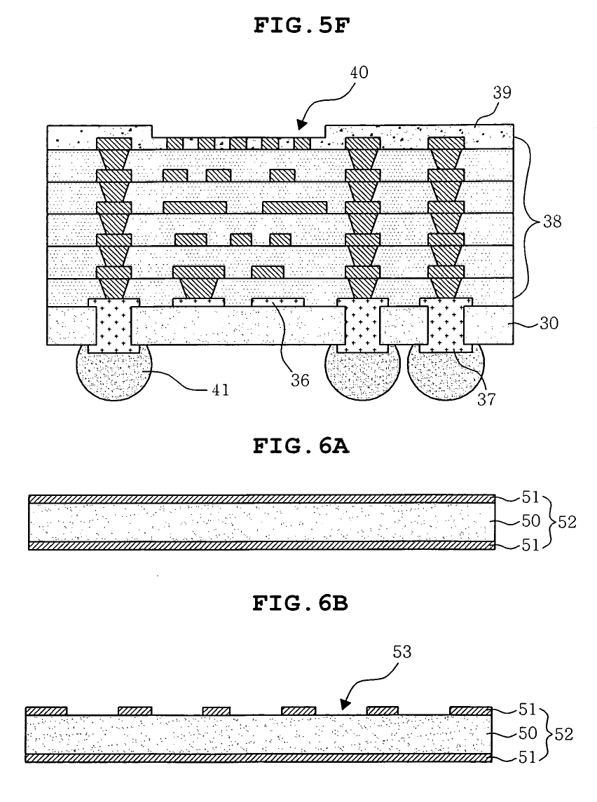

FIG. 5 is sectional views showing a process of manufacturing the multilayered printed circuit board of FIG. 2. Hereinafter, the process of manufacturing the multilayered circuit board of FIG. 2 will be described with reference to FIG. 5.

First, as shown in FIG. 5A, a copper clad laminate (CCL) 32, in which an insulating resin layer 30 is coated with copper foil 31 on both sides thereof, is provided. Here, as the copper clad laminate (CCL) 32, conventional epoxy resin, phenol resins, and the like may be used.

Subsequently, as shown in FIG. 5B, via holes 33 are formed through both sides of the copper clad laminate (CCL) 32, and openings 34 for forming circuit patterns are formed by patterning the copper foil applied on one side thereof.

Here, the via holes are formed through drilling work using a CNC (computer numerical control) drill, a CO₂ laser drill, or a YAG (yttrium aluminum gamet) drill. After the formation of the via holes, deburring and desmearing processes are performed to remove the burrs and smears generated by the drilling work.

The openings 34 are places in which circuit patterns are formed by charging conductive paste thereinto. This openings may be formed by forming an etching resist layer, such as a dry film, etc., on the surface of copper foil layered on one side of the copper clad laminate 32 and then removing the copper foil 31 from the portion on which the etching resist layer is not formed. In this case, the openings 34 are formed only in one side of the double-sided copper clad laminate 32 on which a build-up layer is subsequently formed.

Subsequently, as shown in FIG. 5C, the via holes 33 and openings 34 are filled with conductive paste 35.

Here, the conductive paste 35 is cured and thus forms circuit layers including circuit patterns later. As the conductive paste 35, conductive materials, such as Ag, Pd, Pt, Ni, and Ag/Pd, may be used. However, this conductive paste must not be etched by the same etchant as that used later to etch copper foil.

Subsequently, as shown in FIG. 5D, copper foil is removed from the double-sided copper clad laminate 32.

Here, the copper foil is removed from the copper clad laminate 32 using an etchant selected from among an iron chloride (FeCl₅) etchant, a copper chloride (CuCl₅) etchant, an alkaline etchant, and a hydrogen peroxide/sulfuric acid (H₂O₂/H₂SO₄) etchant. In this case, the conductive paste 35 is not etched using this etchant.

As described above, when copper foil is removed from the copper clad laminate 32, the conductive paste, which is charged in the openings 34 and via holes 33, is protruded in the upward direction of the insulating resin layer 30 to the same height as the thickness of the copper foil. The protruded conductive paste forms a first circuit layer, including circuit patterns 36, on one side of the copper clad laminate 32, and forms a second circuit layer, including connecting pads 37, on the other side thereof. This copper clad laminate 32, from which copper foil is removed, functions later as a support for supporting a build-up layer, so that it prevents the build-up layer from bending and serves to decrease the thickness of the build-up layer, thereby enabling the manufacture of a thin printed circuit board.

Meanwhile, in FIG. 5D, a process of simultaneously removing the copper foils formed on both sides of the copper clad laminate is shown, but, in the present invention, only the copper foil formed on one side of the copper clad laminate, on which circuit patterns 36 are formed, may be removed, and then the copper foil formed on the other side thereof may be subsequently removed. The former process is advantageous in that the manufacturing time is reduced because an additional process of removing the copper foil formed on the other side of the copper clad laminate is not required. In contrast, the latter process is advantageous in that, in subsequent processes, the copper clad laminate, from which the copper foil is removed, functions as a support for supporting a build-up layer later more strongly.

Subsequently, as shown in FIG. 5E, a build-up layer 38 including a plurality of insulating layers and a plurality of circuit layers is formed on the first circuit layer. Here, the build-up layer 38 may be formed using a general build-up method.

Here, the build-up layer 38 is interlayer-connected through the via holes, and the first circuit layer is connected with the circuit layers of the build-up layer 38 through the via holes.

Further, the plurality of insulating layers may be formed of a commonly-used epoxy resin, a glass epoxy resin, an alumina-containing epoxy resin, or the like, but the present invention is not limited thereto. Further, the thickness of the insulating layers may be variously changed if necessary, and, as described above, the insulating layers can be thinly formed because they serve as a support of the copper clad laminate.

Subsequently, as shown in FIG. 5F, a solder resist layer 39 is formed on the outermost layer of the build-up layer 38, and an opening 40 is formed in the solder resist layer such that connecting terminals, formed in the outermost layer of the build-up layer 38, protrude to be connected with other electronic parts. Here, this opening 40 can be formed through mechanical working, such as LDA (Laser Direct Ablation).

Meanwhile, since the insulating resin layer formed by removing the copper foil from the copper clad laminate functions as a solder resist layer for protecting the lowermost circuit patterns, an additional PSR process is not required.

Further, solder balls 41 for connecting a main board or electronic parts therewith may be attached to the connecting pads 37 of the second circuit layer.

Through the above processes, the multilayered printed circuit board shown in FIG. 2 is manufactured.

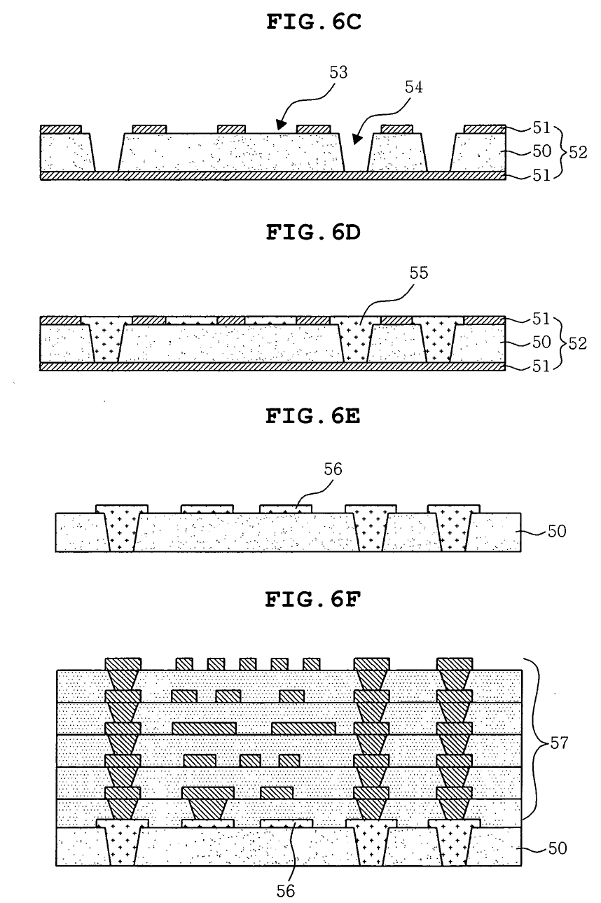

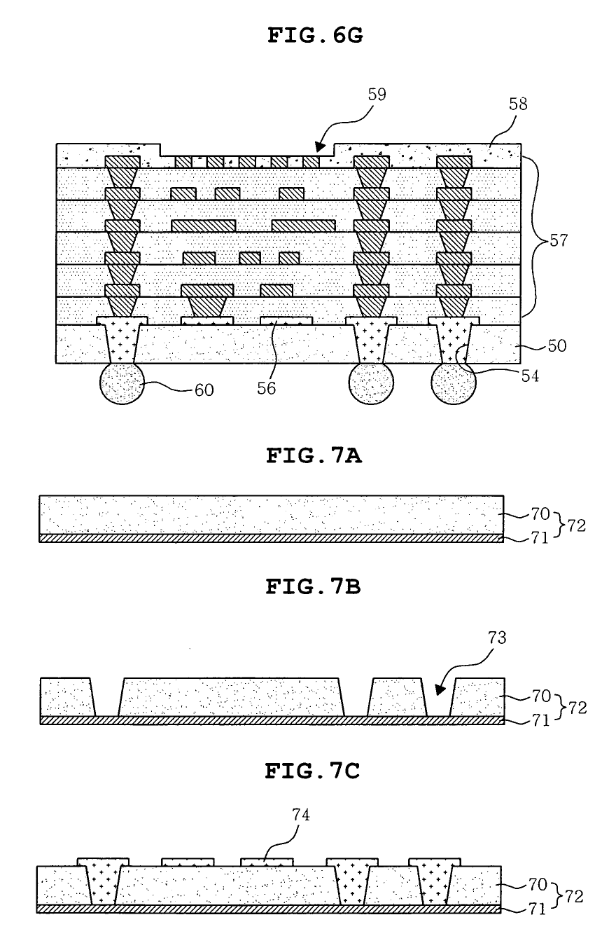

FIG. 6 is sectional views showing the process of manufacturing the multilayered printed circuit board of FIG. 3. Hereinafter, the process of manufacturing the multilayered circuit board of FIG. 3 will be described with reference to FIG. 6. Here, the detailed description of constitutions and processes the same as in the previous embodiment will be omitted.

First, as shown in FIG. 6A, a copper clad laminate (CCL) 52 in which an insulating resin layer 50 is coated with copper foil 51 on both sides thereof is provided.

Subsequently, as shown in FIG. 6B, openings 53 for forming circuit patterns are formed by patterning the copper foil applied on one side of the copper clad laminate (CCL) 52.

Subsequently, as shown in FIG. 6C, blind via holes 54 are formed through both sides of the copper clad laminate (CCL) 52.

Here, the blind via holes 54 are formed in the openings 53. That is, since the openings 53 are previously formed by removing the copper foil located on the portions in which the blind via holes are formed without additionally removing the copper foil, the blind via holes 54 can be more easily formed.

Subsequently, as shown in FIG. 6D, the blind via holes 54 and openings 53 are filled with conductive paste 55.

Subsequently, as shown in FIG. 6E, copper foil 51 is removed from the double-sided copper clad laminate 52.

As described above, when copper foil is removed from the copper clad laminate 52, the conductive paste, which is charged in the openings 53 and blind via holes 54, protrudes in the upward direction of the insulating resin layer 50 to the same height as the thickness of the copper foil in one side of the copper clad laminate 52. The protruded conductive paste forms a first circuit layer, including circuit patterns 56, on one side of the copper clad laminate 52. However, no circuit layer is formed on the other side of the copper clad laminate 52. The reason is that conductive paste is charged in the blind via holes 54.

Meanwhile, since connecting pads are not additionally formed on the other side of the copper clad laminate 52, solder balls 60 are directly connected to the conductive paste, that is, connection parts, charged in the blind via holes 54, at the time of connecting a main board or other electronic parts therewith, and thus the diameters of the solder balls 60 are also decreased. Therefore, the solder balls 60 do not interfere with each other even when the pitch therebetween is short.

Meanwhile, since the copper clad laminate 52, from which copper foil is removed, serves to support the build-up layer, a thin coreless printed circuit board can be easily manufactured. Further, since the copper clad laminate 52, from which copper foil is removed, serves as an insulating layer, no additional PSR process is required.

Subsequently, as shown in FIG. 6F, a build-up layer 57 including a plurality of insulating layers and a plurality of circuit layers is formed on the first circuit layer.

Subsequently, as shown in FIG. 6G, a solder resist layer 58 is formed on the uppermost layer of the build-up layer 57, and an opening 59 is formed in the solder resist layer 58 such that connecting terminals, formed in the uppermost layer of the build-up layer 57, protrude to be connected with other electronic parts.

Through the above processes, the multilayered printed circuit board, shown in FIG. 3, is manufactured.

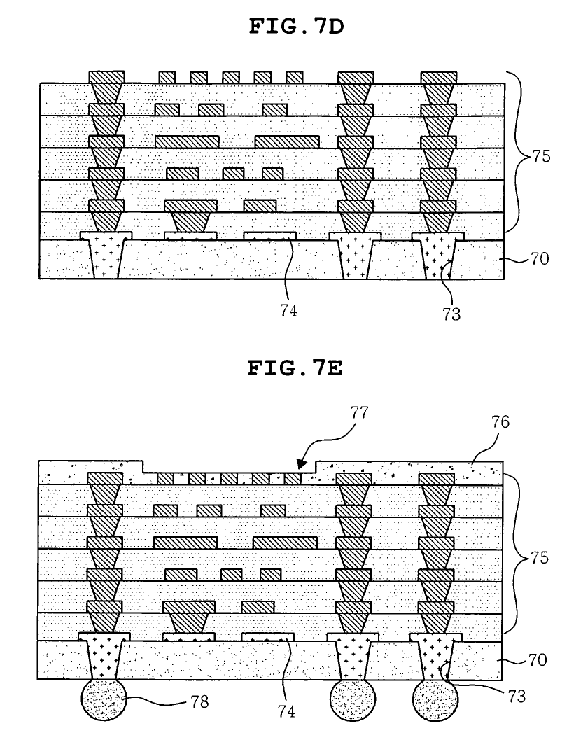

FIG. 7 is sectional views showing the process of manufacturing the multilayered printed circuit board of FIG. 4. Hereinafter, the process of manufacturing the multilayered circuit board of FIG. 4 will be described with reference to FIG. 7. Here, the detailed description of constitutions and processes the same as in the previous embodiment will be omitted.

First, as shown in FIG. 7A, a copper clad laminate (CCL) 72, in which an insulating resin layer 70 is coated with copper foil 71 on one side thereof, is provided.

Subsequently, as shown in FIG. 7B, blind via holes 73 are formed in the copper clad laminate (CCL) 72.

Subsequently, as shown in FIG. 7C, a circuit layer including circuit patterns 74 is formed on the insulating resin layer 70 using a general semi-additive circuit pattern forming method.

Subsequently, as shown in FIG. 7D, a build-up layer including a plurality of insulating layers and a plurality of circuit layers is formed on the circuit layer including the circuit patterns 74, and the copper foil remaining on the insulation resin layer 70 is removed. In this case, since connecting pads are not additionally formed on the other side of the copper clad laminate 72, solder balls 78 are directly connected to the copper plating, that is, connection part, of the blind via holes 73 at the time of connecting a main board or other electronic parts therewith.

Subsequently, as shown in FIG. 7E, a solder resist layer 76 is formed on the uppermost layer of the build-up layer 75, and an opening 77 is formed in the solder resist layer 76 such that connecting terminals, formed in the uppermost layer of the build-up layer 75, protrude to be connected with other electronic parts.

Through the above processes, the multilayered printed circuit board, shown in FIG. 4, is manufactured.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A multilayered printed circuit board, comprising:
an insulating resin layer having via holes, on one side of which a first circuit layer including circuit patterns is formed, and on the other side of which a second circuit layer, including connecting pads for attaching solder balls thereto, is formed, the connecting pads protruding over the via holes;
a build-up layer formed on the first circuit layer, the build-up layer including a plurality of insulating layers and a plurality of circuit layers; and
a solder resist layer formed on an outermost layer of the build-up layer.

2. The multilayered printed circuit board according to claim 1, wherein the first circuit layer and the second circuit layer are formed of silver (Ag) paste.

3. The multilayered printed circuit board according to claim 1, further comprising:
solder balls attached to the connecting pads of the second circuit layer.

4. A multilayered printed circuit board, comprising:
an insulating resin layer having via holes, on one side of which a first circuit layer including circuit patterns is formed, and on the other side of which connection parts for attaching solder balls thereto are formed, the connection parts corresponding to surfaces of the via holes;
a build-up layer formed on the first circuit layer, the build-up layer including a plurality of insulating layers and a plurality of circuit layers; and
a solder resist layer formed on an outermost layer of the build-up layer.

5. The multilayered printed circuit board according to claim 4, wherein the circuit patterns and the via holes are formed of silver (Ag) paste or copper plating.

6. The multilayered printed circuit board according to claim 4, further comprising:
solder balls directly connected to the via holes in the other side of the insulating resin layer.

7. A method of manufacturing a multilayered circuit board, comprising:
providing a double-sided copper clad laminate including via holes formed therethrough and openings for forming circuit patterns, formed by patterning copper foil formed on one side thereof;
filling the via holes and the openings with conductive paste;
removing the copper foil from the double-sided copper clad laminate to form a first circuit layer including circuit patterns on one side thereof and to form a second circuit layer including connecting pads for attaching solder balls thereto on the other side thereof;
forming a build-up layer on the first circuit layer, the build-up layer including a plurality of insulating layers and a plurality of circuit layers; and
forming a solder resist layer on an outermost layer of the build-up layer.

8. The method of manufacturing a multilayered printed circuit board according to claim 7, wherein the via holes are formed through laser drilling or mechanical drilling.

9. The method of manufacturing a multilayered printed circuit board according to claim 7, further comprising: after the forming the solder resist layer, forming an opening in the solder resist layer through LDA (Laser Direct Ablation).

10. The method of manufacturing a multilayered printed circuit board according to claim 7, wherein, in the removing the copper foil from the double-sided copper clad laminate, the copper foil is removed by etching it using an etchant selected from among an iron chloride etchant, a copper chloride etchant, an alkaline etchant, and a hydrogen peroxide/sulfuric acid etchant.

11. The method of manufacturing a multilayered printed circuit board according to claim 7, wherein the conductive paste is not removed using the etchant.

12. A method of manufacturing a multilayered circuit board, comprising:
providing a double-sided copper clad laminate including blind via holes formed therethrough and openings for forming circuit patterns, formed by patterning copper foil formed on one side thereof;
filling the blind via holes and the openings with conductive paste;
removing the copper foil from the double-sided copper clad laminate to form a first circuit layer including circuit patterns on one side thereof and to form connection parts for attaching solder balls thereto on the other side thereof;
forming a build-up layer on the first circuit layer, the build-up layer including a plurality of insulating layers and a plurality of circuit layers; and
forming a solder resist layer on an outermost layer of the build-up layer.

13. The method of manufacturing a multilayered printed circuit board according to claim 12, wherein the blind via holes are formed through laser drilling.

14. The method of manufacturing a multilayered printed circuit board according to claim 12, further comprising: after the forming the solder resist layer, forming an opening in the solder resist layer through LDA (Laser Direct Ablation).

15. The method of manufacturing a multilayered printed circuit board according to claim 12, wherein, in the removing the copper foil from the double-sided copper clad laminate, the copper foil is removed by etching it using an etchant selected from among an iron chloride etchant, a copper chloride etchant, an alkaline etchant, and a hydrogen peroxide/sulfuric acid etchant.

16. The method of manufacturing a multilayered printed circuit board according to claim 12, wherein the conductive paste is not removed by the etchant.

17. A method of manufacturing a multilayered circuit board, comprising:
providing a one-sided copper clad laminate including blind via holes formed therethrough and an insulating resin layer coated with copper foil on one side thereof;
forming a circuit layer on the other side of the insulating resin layer through copper plating;
forming a build-up layer on the circuit layer, the build-up layer including a plurality of insulating layers and a plurality of circuit layers;
removing the copper foil from the one-sided copper clad laminate to form connection parts for attaching solder balls thereto on one side thereof; and
forming a solder resist layer on an outermost layer of the build-up layer.

18. The method of manufacturing a multilayered printed circuit board according to claim 17, wherein the blind via holes are formed through laser drilling.

19. The method of manufacturing a multilayered printed circuit board according to claim 17, further comprising: after the forming the solder resist layer, forming an opening in the solder resist layer through LDA (Laser Direct Ablation).
